(19) United States
(12) Patent Application Publication
(10) Pub. No.: US 2026/0155099 A1
(43) Pub. Date: Jun. 4, 2026

(54) DISPLAY DEVICE

(71) Applicant: LG Display Co., Ltd., Seoul (KR)

(72) Inventors: Booheung Lee, Gimpo-si (KR); SungHun Kim, Iksan-si (KR); HyeonJu Tak, Suwon-si (KR)

(73) Assignee: LG Display Co., Ltd., Seoul (KR)

(21) Appl. No.: 19/283,908

(22) Filed: Jul. 29, 2025

(30) Foreign Application Priority Data
Dec. 4, 2024 (KR) 10-2024-0178596

(51) Int. Cl. G09G 3/3233; G09G 3/3266; H10H 29/855

(52) U.S. Cl. CPC G09G 3/3233; G09G 3/3266; H10H 29/855; G09G 2300/0426; G09G 2300/0465; G09G 2300/0819; G09G 2300/0852; G09G 2300/0861; G09G 2310/08; G09G 2320/068; G09G 2330/021; G09G 2340/0435

(57) ABSTRACT

Provided is a display device. The display device includes a first light emitting diode and a second light emitting diode; a driving transistor connected between a first node and a third node to control a driving current flowing through the first light emitting diode and the second light emitting diode; a first mode selection unit connected between the first node and a first power line configured to supply a first power voltage, the first mode selection unit being configured to operate according to a mode signal; and a second mode selection unit connected between the third node and the first light emitting diode and the second light emitting diode, the second mode selection unit being configured to operate according to the mode signal.

### CROSS-REFERENCE TO RELATED APPLICATION

This application claims the priority of Korean Patent Application No. 10-2024-0178596, filed on Dec. 4, 2024, in the Korean Intellectual Property Office, the disclosure of which is incorporated herein by reference.

### BACKGROUND

### Field

The present disclosure relates to a display device and, more particularly, to a display device capable of implementing a high pixels per inch (PPI) and a high resolution.

### Description of the Related Art

Generally, display devices are widely used as display screens for various electronic devices, such as mobile communication terminals, electronic notebooks, electronic books, portable multimedia players (PMPs), ultra mobile PCs (UMPC), mobile phones, smart phones, tablet PCs (Personal Computers), electronic pads, wearable devices, watch phones, portable information devices, navigation, vehicle control display devices, televisions, laptops, and monitors.

Recently, display devices implementing a maximum or increased screen area by reducing a bezel area in which images are not displayed with the same size of display panel are being studied and developed.

### SUMMARY

An object to be achieved by the present disclosure is to provide a display device capable of implementing a high pixels per inch (PPI) and a high resolution.

Another object to be achieved by the present disclosure is to provide a display device with a minimized or reduced bezel area.

Objects of the present disclosure are not limited to the above-mentioned objects, and other objects, which are not mentioned above, can be clearly understood by those skilled in the art from the following descriptions.

According to an aspect of the present disclosure, a display device includes a first light emitting diode and a second light emitting diode; a driving transistor connected between a first node and a third node to control a driving current flowing through the first light emitting diode and the second light emitting diode; a first mode selection unit connected between the first node and a first power line configured to supply a first power voltage, the first mode selection unit being configured to operate according to a mode signal; and a second mode selection unit connected between the third node and the first light emitting diode and the second light emitting diode, the second node selection unit being configured to operate according to the mode signal.

According to another aspect of the present disclosure, a display device includes a substrate including an active area in which a plurality of sub pixels is disposed and a non-active area which encloses the active area; and a gate driver disposed in the non-active area. Each of the plurality of sub pixels includes a first light emitting diode and a second light emitting diode; a driving transistor connected between a first node and a third node; a first transistor connected between the third node and a second node corresponding to a gate electrode of the driving transistor; a second transistor connected between a data line configured to receive a data signal and the first node; a third transistor connected between a first power line configured to supply a first power voltage and the first node to operate according to a first mode signal; a fourth transistor connected between the first power line and the first node to operate according to a second mode signal; a fifth transistor connected between the driving transistor and the first light emitting diode to operate according to the first mode signal; a sixth transistor connected between the driving transistor and the second light emitting diode to operate according to the second mode signal; a seventh transistor connected between a second power line configured to supply a second power voltage and the first node; an eighth transistor connected between a third power line configured to supply a third power voltage and a fourth node corresponding to a first electrode of the first light emitting diode; a ninth transistor connected between the third power line and a fifth node corresponding to a first electrode of the second light emitting diode; a tenth transistor connected between a fourth power line configured to supply a fourth power voltage and the second node; and a storage capacitor connected between the first power line and the second node.

Other detailed matters of the example embodiments are included in the detailed description and the drawings.

According to an aspect of the present disclosure, a display device which implements a high pixels per inch (PPI) and a high resolution by reducing a number of wiring lines is provided.

According to an aspect of the present disclosure, a display device with a minimized or reduced bezel area by reducing a gate driver is provided.

The effects according to the present disclosure are not limited to the contents exemplified above, and more various effects are included in the present specification.

Additional features and aspects of the present disclosure are set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

It is to be understood that both the foregoing general description and the following detailed description of the present disclosure are by way of example and are intended to provide further explanation of the disclosures as claimed.

### BRIEF DESCRIPTION OF DRAWINGS

The accompanying drawings, which are included to provide a further understanding of the present disclosure and are incorporated in and constitute a part of this application, illustrate various aspects of the disclosure and together with the description serve to explain various principles of the present disclosure. In the drawings:

FIG. 1 is a block diagram of a display device according to an example embodiment of the present disclosure;

FIG. 2 is a block diagram of a gate driver of a display device according to an example embodiment of the present disclosure;

FIG. 3 is a plan view of a display device according to an example embodiment of the present disclosure;

FIG. 4 is a circuit diagram of a sub pixel of a display device according to an example embodiment of the present disclosure;

FIGS. 5A and 5B are waveform charts for explaining a sub pixel circuit of FIG. 4;

FIG. 6 is a circuit diagram of a sub pixel of a display device according to another example embodiment of the present disclosure;

FIG. 7 is a plan view of a sub pixel of a display device according to still another example embodiment of the present disclosure;

FIG. 8 is a circuit diagram for a sub pixel of FIG. 7;

FIG. 9 is a plan view of a sub pixel of a display device according to still another example embodiment of the present disclosure; and

FIG. 10 is a circuit diagram for a sub pixel of FIG. 9.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but can be implemented in various other forms. The example embodiments described below are provided by way of example only so that those skilled in the art can more fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with a more limiting term like “only”. Any references to singular may include plural, and vice versa, unless expressly stated otherwise.

Components are interpreted to include an ordinary error range even if not expressly stated.

Where the position relation between two parts is described using the terms such as “on”, “above”, “below”, and “next”, one or more parts may be positioned between the two parts unless the terms are used with a more limiting term like “immediately” or “directly”.

Where temporal relationships are described, terms such as “after,” “following,” “subsequent to,” or “before,” etc., may include non-consecutive cases unless a more limiting term like “immediately” or “directly” is used.

Terms such as “first,” “second,” etc., may be used to describe various components, but these components are not limited by these terms. These terms are merely used to refer to one component separately from another. Therefore, a first component mentioned herein could be a second component, and vice versa, within the technical scope of the present disclosure.

In describing the components of the present disclosure, terms such as first, second, A, B, (a), or (b) may be used. These terms are only intended to refer to that one component separately from other components, and the nature, order, sequence, or number of the respective component is not limited by these terms.

Where a component is described as being “connected,” “coupled,” “joined,” or “attached” to another component, it should be understood that the component may be directly connected, coupled, joined, or attached to the other component, but unless explicitly specified otherwise, it may also be indirectly connected, coupled, joined, or attached with another component intervening between each component.

Where a component or layer is described as being “in contact with” or “overlapping” another component or layer, the component or layer may directly contact or overlap the other component or layer, but unless explicitly specified otherwise, it should be understood that it may also indirectly contact or overlap with another component intervening between each component.

The term “at least one” should be understood to include all combinations of one or more of the associated components. For example, “at least one of first, second, and third components” means not only the first, second, or third component, but also includes all combinations of two or more components from among the first, second, and third components.

The terms “first direction”, “second direction”, “third direction”, “X-axis direction”, “Y-axis direction”, and “Z-axis direction” should not be interpreted solely as geometric relationships perpendicular to each other, but may indicate broader directionality within the range where the configuration of the present disclosure can function.

The features of various example embodiments in the present disclosure may be partially or wholly combined or associated with each other, various technical interlocking and operations are possible, and each example embodiment may be implemented independently of each other or may be implemented together in an associated relationship.

Hereinafter, a display apparatus according to example embodiments of the present disclosure will be described in detail with reference to accompanying drawings.

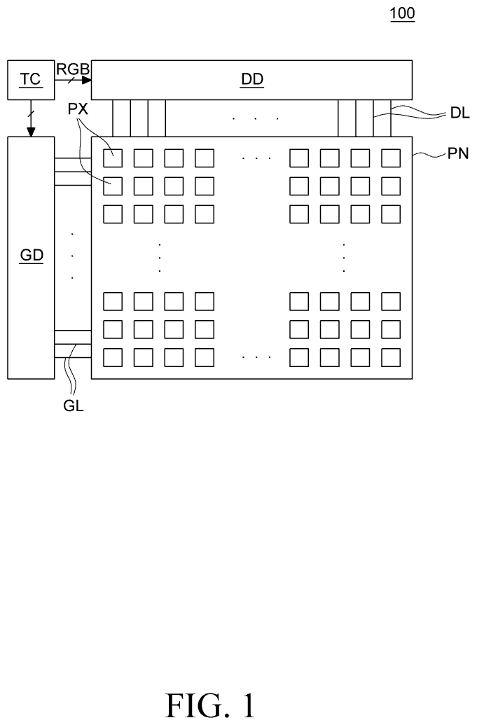

FIG. 1 is a block diagram of a display device according to an example embodiment of the present disclosure.

The display device 100 according to the example embodiment of the present disclosure may be applied to the electroluminescent display device. The electroluminescent display device may use an organic light emitting diode (OLED) display device, a quantum dot light emitting diode display device, or an inorganic light emitting diode display device.

As shown in FIG. 1, the display device 100 may include a display panel PN, a data driver DD, a gate driver GD, and a timing controller TC.

The display panel PN may generate images to be provided to the user. For example, the display panel PN may generate and display images to be provided to the user through a pixel PX in which a plurality of sub pixel circuits is disposed.

The data driver DD, the gate driver GD, and the timing controller TC may supply signals for operation of individual pixels PX through signal lines. The signal lines, for example, may include data lines DL and gate lines GL.

The data lines DL are disposed in a column direction and may include a plurality of wiring lines connected to pixels PX disposed in one column direction and the gate lines GL are disposed in a row direction and may include a plurality of wiring lines connected to pixels PX disposed in one row direction.

In some cases, the display device 100 may further include a power unit. In this case, a power voltage for an operation of the pixel PX may be supplied through a power line which connects the power unit and the display panel PN. For example, the power unit may supply a high potential driving voltage, a low potential driving voltage, and an initialization voltage to the pixel PX. The high potential driving voltage, the low potential driving voltage, and the initialization voltage may be a predetermined level of constant voltage. Further, the power unit may supply a power voltage to the data driving circuit DD and the gate driving circuit GD. The data driving circuit DD and the gate driving circuit GD may be driven based on the power voltage supplied from the power unit.

For example, the data driver DD may apply a data signal to each pixel PX through the data lines DL. The gate driver GD may apply a gate signal to each pixel PX through the gate lines GL. The power unit may supply a power voltage to each pixel PX through the power voltage supply lines.

The timing controller TC may control the data driver DD and the gate driver GD. For example, the timing controller TC rearranges digital video data input from the outside in accordance with a resolution of the display panel PN to supply the digital video data to the data driver DD.

The data driver DD converts digital video data input from the timing controller TD into an analog data voltage based on the data control signal to supply the converted analog data voltage to the plurality of data lines DL.

The gate driver GD may generate a scan signal and a mode signal based on the gate control signal. The gate driver GD may include a scan driver and a mode signal driver. The scan driver generates a scan signal in a row sequential manner to drive at least one or more scan lines connected to each pixel row to supply the scan signal to the scan lines. The mode signal driver generates a mode signal in a row sequential manner to drive at least one or more mode signal lines connected to each pixel row to supply the mode signal to the mode signal lines.

According to the example embodiment, the gate driver GD may be disposed in the display panel PN in a gate-driver in panel (GIP) manner. For example, the gate driver GD may be divided into a plurality of circuits to be disposed on at least two side surfaces of the display panel PN.

The display panel PN may include an active area and a non-active area which encloses the active area.

The active area of the display panel PN may include a plurality of pixels PX disposed in a row direction and a column direction. The pixel PX may be disposed in an intersecting area of a plurality of data lines DL and a plurality of gate lines GL.

One pixel PX may include a plurality of sub pixels which emits different color light. For example, the pixel PX uses three sub pixels to implement blue, red, and green. However, this is not limited thereto and, in some cases, the pixel PX may further include a sub pixel for further implementing a specific color (for example, white).

In the pixel PX, an area which implements blue may be referred to as a blue sub pixel, an area which implements red may be referred to as a red sub pixel, and an area which implements green may be referred to as a green sub pixel.

Each of the plurality of sub pixels may include a first light emitting diode and a second light emitting diode which emit same color light, a first lens which refracts light from the first light emitting diode to a specific direction, and a second lens which refracts light from the second light emitting diode to a specific direction. Therefore, the first lens and the second lens may limit the viewing angle of each of the plurality of sub pixels.

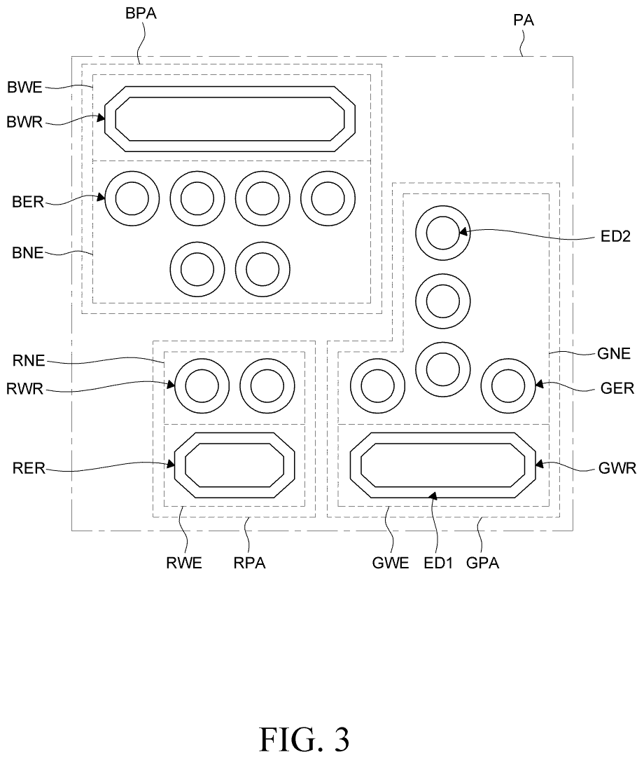

The first lens and the second lens will be described in detail below with reference to FIG. 3.

The non-active area may be disposed along the circumference of the active area. Various components for driving a plurality of sub pixels disposed in the pixel PX may be disposed in the non-active area. For example, in the non-active area, at least a part of a signal line which transmits signals, a power line which applies a power, and a gate driver GD may be disposed. The non-active area may be referred to as a bezel area.

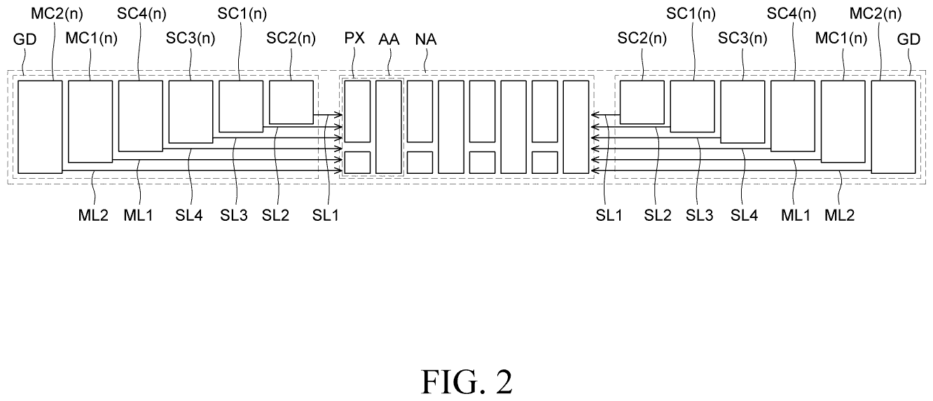

FIG. 2 is a block diagram of a gate driver of a display device according to an example embodiment of the present disclosure. In FIG. 2, for the convenience of description, only a gate driver GD for one pixel line is illustrated.

As shown in FIG. 2, the gate driver GD is symmetrically disposed in non-active areas NA in both sides of the active area AA to supply the scan signal and the mode signal to the plurality of pixels PX.

Each of the gate drivers GD may include a first scan driver SC1(n), a second scan driver SC2(n), a third scan driver SC3(n), a fourth scan driver SC4(n), a first mode driver MC1(n), and a second mode driver MC2(n). Each of the first scan driver SC1(n), the second scan driver SC2(n), the third scan driver SC3(n), the fourth scan driver SC4(n), the first mode driver MC1(n), and the second mode driver MC2(n) may include a plurality of stages.

In each of the gate drivers GD, the second scan driver SC2(n), the first scan driver SC1(n), the third scan driver SC3(n), the fourth scan driver SC4(n), the second mode driver MC2(n), and the first mode driver MC1(n) may be disposed in this order from a position adjacent to the active area AA. However, it is not limited thereto, and it may be changed depending on the design.

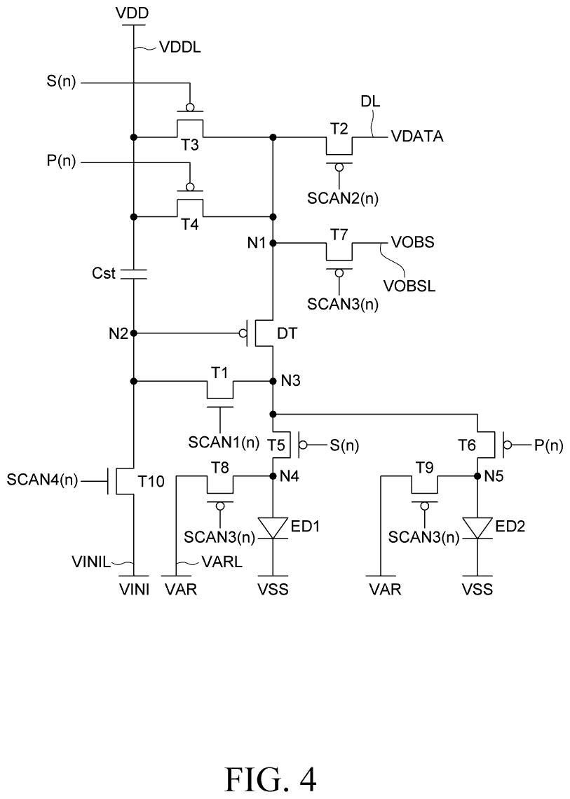

The first scan driver SC1(n) may output the first scan signal (SCAN1(n) of FIG. 4) through the first scan line SL1. The second scan driver SC2(n) may output the second scan signal (SCAN2(n) of FIG. 4) through the second scan line SL2. The third scan driver SC3(n) may output the third scan signal (SCAN3(n) of FIG. 4) through the third scan line SL3. The fourth scan driver SC4(n) may output the fourth scan signal (SCAN4(n) of FIG. 4) through the fourth scan line SL4. The first mode driver MC1(n) may output the first mode signal (S(n) of FIG. 4) through the first mode line ML1. The second mode driver MC2(n) may output the second mode signal (P(n) of FIG. 4) through the second mode line ML2.

One scan driver of the first scan driver SC1(n), the second scan driver SC2(n), the third scan driver SC3(n), and the fourth scan driver SC4(n) may be configured by a shift register circuit and the remaining scan drivers and the first mode driver MC1(n) and the second mode driver MC2(n) may be configured by edge trigger circuits. For example, the second scan driver SC2(n) may be configured by the shift register circuit and the first scan driver SC1(n), the third scan driver SC3(n), the fourth scan driver SC4(n), the first mode driver MC1(n), and the second mode driver MC2(n) may be configured by edge trigger circuits. However, it is not limited thereto, and it may be changed depending on the design.

The first scan signal SCAN1(n) may be used as a signal to drive a transistor (for example, a compensation transistor) included in the sub pixel circuit. The second scan signal SCAN2(n) may be used as a signal to drive a transistor (for example, a data supply transistor) included in the sub pixel circuit. The third scan signal SCAN3(n) may be used as a signal to drive a transistor (for example, a bias transistor) included in the sub pixel circuit. The fourth scan signal SCAN4(n) may be used as a signal to drive a transistor (for example, an initialization transistor) included in the sub pixel circuit. The first mode signal S(n) and the second mode signal P(n) may be used as signals to drive a transistor (for example, an emission control transistor) included in the sub pixel circuit. For example, when the emission control transistor of the pixels is controlled using the first mode signal S(n) and the second mode signal P(n), the plurality of light emitting diodes may selectively emit light.

FIG. 3 is a plan view of a display device according to an example embodiment of the present disclosure. FIG. 3 illustrates a plane of the pixel area PA when three sub pixels are disposed in the pixel area PA.

As shown in FIG. 3, the pixel area PA may include a blue sub pixel area BPA which implements blue, a red sub pixel area RPA which implements red, and a green sub pixel area GPA which implements green. According to the example embodiment, the blue sub pixel area BPA may correspond to a first sub pixel, the red sub pixel area RPA may correspond to a second sub pixel, and the green sub pixel GPA may correspond to a third sub pixel. The sub pixel circuit may correspond to each sub pixel. A corresponding sub pixel circuit may be disposed in every sub pixel.

The pixel area PA may include first lens areas BWE, RWE, and GWE and second lens areas BNE, RNE, and GNE which provide different viewing angles.

In the first lens areas BWE, RWE, and GWE, the first light emitting diode (a first light emitting diode ED1 of FIG. 4) and first lenses BWR, RWR, and GWR may be disposed. The first lenses BWR, RWR, and GWR may be disposed on the first lens areas BWE, RWE, and GWE of each pixel area PA. For example, light generated by the first light emitting diode ED1 in each pixel area PA may be emitted through the first lenses BWR, RWR, and GWR of the pixel area PA. The first lenses BWR, RWR, and GWR may have a shape that does not limit light of at least one direction. The first lenses BWR, RWR, and GWR may provide a viewing angle with a first value. For example, a flat shape of the first lenses BWR, RWR, and GWR in each pixel area PA may have a bar shape which extends in a first direction.

In this case, a traveling direction of light emitted from the first lens areas BWE, RWE, and GWE of the pixel area PA may not be limited to the first direction. For example, contents (or images) provided through the first lens areas BWE, RWE, and GWE of the pixel area PA may be shared by surrounding people which is adjacent to the user in the first direction. When the contents are provided through the first lens areas BWE, RWE, and GWE, the contents are provided at a viewing angle range with a first value which is wider than a viewing angle range with a second value supplied by the second lens areas BNE, RNE, and GNE and this may be referred to as a first mode or a wide field-of-view mode.

In the second lens areas BNE, RNE, and GNE, the second light emitting diode (the second light emitting diode ED2 of FIG. 4) and the second lenses BNR, RNR, and GNR may be disposed. The second lenses BNR, RNR, and GNR may be located on the second lens areas BNE, RNE, and GNE of each pixel area PA. Light generated by the second light emitting diode ED2 in each pixel area PA may be emitted through the second lenses BNR, RNR, and GNR of the pixel area PA. A traveling direction of light which passes through the second lenses BNR, RNR, and GNR may be limited to the first direction and/or the second direction. The second lenses BNR, RNR, and GNR may provide a viewing angle with a second value. For example, a flat shape of the second lenses BNR, RNR, and GNR located in the pixel area PA may have a circular shape.

In this case, a traveling direction of light emitted from the second lens areas BNE, RNE, and GNE of each pixel area PA may be limited to the first direction and the second direction. For example, the contents supplied by the second lens areas BNE, RNE, and GNE of the pixel area PA may not be shared by the people around the user. When the contents are provided through the second lens areas BNE, RNE, and GNE, the contents are provided at a viewing angle range with a second value which is narrower than the viewing angle range with the first value supplied by the first lens areas BWE, RWE, and GWE and this may be referred to as a second mode or a narrow field-of-view mode.

In the first lens areas BWE, RWE, and GWE of the pixel area PA, one first lens BWR, RWR, or GWR and one first light emitting diode (the first light emitting diode ED1 of FIG. 4) may be disposed. In the second lens areas BNE, RNE, and GNE of the pixel area PA, the second light emitting diode (the second light emitting diode ED2 of FIG. 4) and a plurality of second lenses BNR, RNR, and GNR may be disposed.

FIG. 4 is a circuit diagram of a sub pixel of a display device according to an example embodiment of the present disclosure. FIG. 4 illustrates an example of a sub pixel circuit which is applicable as a sub pixel circuit of a display device according to an example embodiment of the present disclosure.

As shown in FIG. 4, the sub pixel circuit controls a driving current which flows through the first light emitting diode ED1 and the second light emitting diode ED2 to drive the first light emitting diode ED1 and the second light emitting diode ED2. The sub pixel circuit may include a driving transistor DT, first to tenth transistors T1 to T10, and a storage capacitor Cst. Each of the transistors DT and T1 to T10 may include a first electrode, a second electrode, and a gate electrode. One of the first electrode and the second electrode may be a source electrode and the other one of the first electrode and the second electrode may be a drain electrode.

Each of the transistors DT and T1 to T10 may be a P-type thin film transistor or an N-type thin film transistor. In the example embodiment of FIG. 4, it is described that the first transistor T1 and the tenth transistor T10 are N-type thin film transistors and the remaining transistors DT, T2 to T9 are P-type thin film transistors. However, it is not limited thereto and depending on the example embodiment, all or some of the transistors DT and T1 to T10 may be P-type thin film transistors or N-type thin film transistors. Further, the N-type thin film transistor may be an oxide thin film transistor and the P-type thin film transistor may be a polycrystalline silicon thin film transistor.

Hereinafter, it is exemplified that the first transistor T1 and the tenth transistor T10 are N-type thin film transistors and the remaining transistors DT, T2 to T9 are P-type thin film transistors. Accordingly, a high voltage is applied to the first transistor T1 and the tenth transistor T10 to be turned on and a low voltage is applied to the remaining transistors DT, T2 to T9 to be turned on.

According to an example, the first transistor T1 which configures the sub pixel circuit may serve as a compensation unit, the second transistor T2 may serve as a data supply unit, and the third transistor T3 and the fourth transistor T4 may serve as a first mode selection unit. The fifth transistor T5 and the sixth transistor T6 may serve as the second mode selection unit, the seventh transistor T7 may serve as a bias unit, and the eighth to tenth transistors T8, T9, and T10 may serve as an initialization unit.

The first light emitting diode ED1 and the second light emitting diode ED2 may include an anode electrode and a cathode electrode. For example, the anode electrode of the first light emitting diode ED1 may be connected to a fourth node N4 and the cathode electrode may be connected to a low potential driving voltage VSS. For example, the anode electrode of the second light emitting diode ED2 may be connected to a fifth node N5 and the cathode electrode may be connected to a low potential driving voltage VSS.

The driving transistor DT may include a first electrode connected to a first node N1, a second electrode connected to a third node N3, and a gate electrode connected to a second node N2. The driving transistor DT may supply a driving current to the first light emitting diode ED1 and the second light emitting diode ED2 based on a voltage of the second node N2 (or a data voltage stored in the storage capacitor Cst to be described below).

The first transistor T1 may include a first electrode connected to the second node N2, a second electrode connected to the third node N3, and a gate electrode which receives a first scan signal Scan1(n). The first transistor T1 is turned on in response to the first scan signal Scan1(n) and is diode-connected between the second node N2 and the third node N3 to sample a threshold voltage Vth of the driving transistor DT.

The storage capacitor Cst may be connected between the second node N2 and the first power voltage line VDDL to which the first power voltage VDD is applied. For example, the first power voltage VDD may be a high potential driving voltage and the first power voltage line VDDL may be a high potential driving voltage line. The storage capacitor Cst may store or maintain the supplied high potential driving voltage VDD.

The second transistor T2 may include a first electrode connected to the data line DL, a second electrode connected to the first node N1, and a gate electrode which receives a second scan signal SCAN2(n). The second transistor T2 may be turned on in response to a second scan signal SCAN2(n) and transmit the data voltage VDATA to the first node N1.

The third transistor T3, the fourth transistor T4, the fifth transistor T5, and the sixth transistor T6 may be connected between the high potential driving voltage line VDDL and the first light emitting diodes ED1 and the second light emitting diode ED2 and form a current movement path through which the driving current Id generated by the driving transistor DT moves.

The third transistor T3 may include a first electrode which is connected to the high potential driving voltage line VDDL to receive the high potential driving voltage VDD, a second electrode connected to the first node N1, and a gate electrode which is connected to the first mode signal line ML1 to receive the first mode signal S(n).

The fourth transistor T4 may include a first electrode which is connected to the high potential driving voltage line VDDL to receive the high potential driving voltage VDD, a second electrode connected to the first node N1, and a gate electrode which is connected to the second mode signal line ML2 to receive the second mode signal P(n).

The fifth transistor T5 may form a current path between the driving transistor DT and the first light emitting diode ED1 when it is driven in a first mode. The fifth transistor T5 may include a first electrode connected to the third node N3, a second electrode connected to the fourth node N4, and a gate electrode which is connected to the first mode signal line ML1 to receive the first mode signal S(n). At this time, the fourth node N4 may be connected to the anode electrode of the first light emitting diode ED1.

The fifth transistor T5 may be turned on or turned off by the first mode signal S(n). Therefore, the fifth transistor T5 may form a current path between the third node N3 and the first light emitting diode ED1 in response to a low level of first mode signal S(n) which is a turn-on level. That is, the fifth transistor T5 may form a current path between the driving transistor DT and the first light emitting diode ED1 in response to a low level of first mode signal S(n). Therefore, the fifth transistor T5 may be referred to as a first emission control transistor which controls emission of the first light emitting diode ED1.

That is, the third transistor and the fifth transistors T3 and T5 are turned on in response to the first mode signal S(n) and in this case, the driving current Id is supplied to the first light emitting diode ED1 and the first light emitting diode ED1 may emit light with a luminance corresponding to the driving current Id.

The sixth transistor T6 may form a current path between the driving transistor DT and the second light emitting diode ED2 when it is driven in a second mode. The sixth transistor T6 may include a first electrode connected to the third node N3, a second electrode connected to the fifth node N5, and a gate electrode which is connected to the second mode signal line ML2 to receive the second mode signal P(n). At this time, the fifth node N5 may be connected to the anode electrode of the second light emitting diode ED2.

The sixth transistor T6 may be turned on or turned off by the second mode signal P(n). Therefore, the sixth transistor T6 may form a current path between the third node N3 and the second light emitting diode ED2 in response to a low level of second mode signal P(n) which is a turn-on level. That is, the sixth transistor T6 may form a current path between the driving transistor DT and the second light emitting diode ED2 in response to a low level of second mode signal P(n). Therefore, the sixth transistor T6 may be referred to as a second emission control transistor which controls emission of the second light emitting diode ED2.

That is, the fourth transistor and the sixth transistors T4 and T6 are turned on in response to the second mode signal P(n) and in this case, the driving current Id is supplied to the second light emitting diode ED2 and the second light emitting diode ED2 may emit light with a luminance corresponding to the driving current Id.

The seventh transistor T7 may include a first electrode connected to a second power voltage line VOBSL to which the second power voltage VOBS is applied, a second electrode connected to the first node N1, and a gate electrode which receives the third scan signal SCAN3(n). For example, the second power voltage VOBS may be a bias voltage and the second power voltage line VOBSL may be a bias voltage line.

The eighth transistor T8 may include a first electrode connected to a third power voltage line VARL to which the third power voltage VAR is applied, a second electrode connected to the fourth node N4, and a gate electrode which receives the third scan signal SCAN3(n). For example, the third power voltage VAR may be a first initialization voltage, and the third power voltage line VAR may be a first initialization voltage line.

The ninth transistor T9 may include a first electrode connected to the third power voltage line VARL to which the third power voltage VAR is applied, a second electrode connected to the fifth node N5, and a gate electrode which receives the third scan signal SCAN3(n). For example, the third power voltage VAR may be a first initialization voltage and the third power voltage line VARL may be a first initialization voltage line.

The eighth transistor T8 and the ninth transistor T9 are turned on in response to the third scan signal SCAN3(n) before the first light emitting diode ED1 and the second light emitting diode ED2 emit light (or after the first light emitting diode ED1 and the second light emitting diode ED2 emit light). Further, the eighth transistor T8 and the ninth transistor T9 may initialize the anode electrodes (or pixel electrodes) of the first light emitting diode ED1 and the second light emitting diode ED2 using the first initialization voltage VAR. The first light emitting diode ED1 and the second light emitting diode ED2 may include a parasitic capacitor formed between an anode electrode and a cathode electrode. The parasitic capacitor is charged while the first light emitting diode ED1 and the second light emitting diode ED2 emit light so that the anode electrodes of the first light emitting diode ED1 and the second light emitting diode ED2 may have a specific voltage. Accordingly, the first initialization voltage VAR is applied to the anode electrodes of the first light emitting diode ED1 and the second light emitting diodes ED2 through the eighth transistor T8 and the ninth transistor T9 to initialize a quantity of charges accumulated in the first light emitting diode ED1 and the second light emitting diodes ED2.

In the present example embodiment, the gate electrodes of the eighth transistor T8 and the ninth transistor T9 are configured to commonly receive the third scan signal SCAN3(n). However, the present disclosure is not essentially limited thereto and the gate electrodes of the eighth transistor T8 and the ninth transistor T9 may be configured to receive separate scan signals to be independently controlled.

The tenth transistor T10 may include a first electrode connected to the fourth power voltage line VINIL to which the fourth power voltage VINI is applied, a second electrode connected to the second node N2, and a gate electrode which receives the fourth scan signal SCAN4(n). For example, the fourth power voltage VINI may be a second initialization voltage, and the fourth power voltage line VINIL may be a second initialization voltage line.

The tenth transistor T10 is turned on in response to the fourth scan signal SCAN4(n) and may initialize the gate electrode of the driving transistor DT using the second initialization voltage VINI. In the gate electrode of the driving transistor DT, unnecessary charges may remain due to the high potential driving voltage VDD stored in the storage capacitor Cst. Accordingly, the second initialization voltage VINI is applied to the gate electrode of the driving transistor DT through the tenth transistor T10 to initialize the remaining quantity of charges.

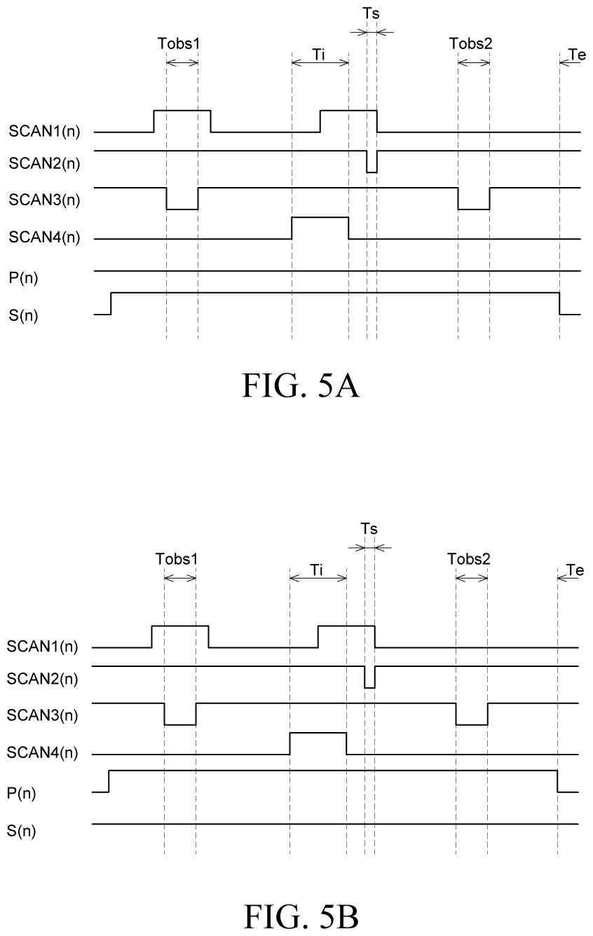

FIGS. 5A and 5B are waveform charts for explaining a sub pixel circuit of FIG. 4. FIGS. 5A and 5B are views for explaining an operation of a scan signal and a mode signal in a refresh period in a sub pixel circuit. FIG. 5A is a view for explaining an operation of the first mode and FIG. 5B is a view for explaining an operation of the second mode.

A display device according to the example embodiment of the present disclosure may operate as a variable refresh rate (VRR) mode display device. In the VRR mode, the pixel is driven at a constant frequency and at a timing when a high speed driving is necessary, a refresh rate at which the data voltage VDATA is updated is increased to operate the pixel. Further, at a timing when the power consumption needs to be lowered or low-speed driving is necessary, the refresh rate is lowered to operate the pixel.

Each of the plurality of pixels PX may be driven by a combination of a refresh frame and a hold frame for one second. In the present disclosure, one set is defined that a combination of a refresh period in which the data voltage VDATA is updated and a hold period in which the data voltage VDATA is not updated is repeated for one second. One set period may be a period in which a combination of the refresh period and the hold period is repeated.

When the pixel is driven at the refresh rate of 120 Hz, the pixel may be driven only with the refresh period. That is, the refresh period may be driven 120 times in one second. One refresh period is 1/120=8.33 ms, and one set period is also 8.33 ms.

When the refresh rate is driven at 60 Hz, the refresh period and the hold period may be alternately driven. That is, the refresh period and the hold period may be alternately driven 60 times each in one second. One refresh period and one hold period are 0.5/60=8.33 ms, and one set period is 16.66 ms.

When the refresh rate is driven at 1 Hz, one frame may be driven with one refresh period and 119 hold periods after the one refresh period. Further, when the refresh rate is driven at 1 Hz, one frame may be driven with a plurality of refresh periods and a plurality of hold periods. At this time, one refresh period and one hold period are 1/120 =8.33 ms, and one set period is 1 s.

In the refresh period, a new data voltage VDATA is charged to apply the new data voltage VDATA to the driving transistor DT and in the hold period, a data voltage VDATA of a previous frame is held to be used as it is. In the meantime, in the hold period, a process of applying the new data voltage VDATA to the driving transistor DT is omitted so that the hold period may also be referred to as a skip period.

Each of the plurality of pixels PX may initialize a voltage which is charged or remains in the sub pixel circuit during the refresh period. Specifically, each of the plurality of pixels PX may remove the influence of the data voltage VDATA and the high potential driving voltage VDD stored in the previous frame in the refresh period. Accordingly, each of the plurality of pixels PX may display an image corresponding to a new data voltage VDATA in the hold period.

Each of the plurality of pixels PX may supply a driving current corresponding to the data voltage VDATA to the first light emitting diode ED1 or the second light emitting diode ED2 to display images and maintain a turn-on state of the first light emitting diode ED1 or the second light emitting diode ED2 during the hold period.

As shown in FIGS. 5A and 5B, in the first mode and the second mode, the difference in the driving signal is the first mode signal S(n) and the second mode signal P(n). In the first mode, only the first light emitting diode ED1 may emit light and in the second mode, only the second light emitting diode ED2 may emit light. In the first mode, to allow only the first light emitting diode ED1 to emit light, the second mode signal P(n) which controls the emission of the second light emitting diode ED2 may be output only at a high level which is a turn-off level. In the second mode, to allow only the second light emitting diode ED2 to emit light, the first mode signal S(n) which controls the emission of the first light emitting diode ED1 may be output only at a high level which is a turn-off level.

As shown in FIGS. 5A and 5B, in the first mode and the second mode, the refresh period may operate including at least one bias interval Tobs1 and Tobs2, an initialization interval Ti, a sampling interval Ts, and an emission interval Te, but this is just an example embodiment and is not necessarily bound to this order.

As shown in FIG. 5A, the pixel circuit may operate including at least one bias interval Tobs1 and Tobs2 during the refresh period.

At least one bias interval Tobs1 and Tobs2 is an interval when the on-bias stress operation OBS which applies a bias voltage VOBS is performed.

In the first bias interval Tobs1 and the second bias interval Tobs2, the first mode control signal S(n) and the second mode control signal P(n) are high voltages and the third transistor T3, the fourth transistor T4, the fifth transistor T5, and the sixth transistor T6 are turned off. The first scan signal SCAN1(n) is a high voltage and the first transistor T1 is turned on. The second scan signal SCAN2(n)is a high voltage, the fourth scan signal SCAN4(n) is a low voltage, and the second transistor T2 and the tenth transistor T10 are turned off. The third scan signal SCAN3(n) is input as a low voltage and the seventh transistor T7, the eighth transistor T8, and the ninth transistor T9 are turned on. As the seventh transistor T7 is turned on, the bias voltage VOBS is applied to the first electrode of the driving transistor DT connected to the first node N1.

Here, the bias voltage VOBS is supplied to the third node N3 which is the second electrode of the driving transistor DT. Therefore, a charging time or charging delay of the voltage of the fourth node N4 and the fifth node N5 which are the anode electrodes of the first light emitting diode ED1 and the second light emitting diode ED2 in the emission period may be reduced. At this time, the driving transistor DT maintains a stronger saturation state.

For example, the higher the bias voltage VOBS, the higher the voltage of the third node N3 which is the drain electrode of the driving transistor DT and the lower the gate-source voltage or the drain-source voltage of the driving transistor DT. Accordingly, the bias voltage VOBS is desirably higher than at least the data voltage VDATA.

At this time, the magnitude of the driving current Id which passes through the driving transistor DT may be reduced and in a positive bias stress situation, the stress of the driving transistor DT is reduced to solve the charging delay of the voltage of the third node N3. In other words, before sampling a threshold voltage Vth of the driving transistor DT, the on-bias stress operation OBS is performed to relieve the hysteresis of the driving transistor DT.

Accordingly, in at least one bias interval Tobs1 and Tobs2, the on-bias stress operation OBS may be defined as an operation of directly applying an appropriate bias voltage to the driving transistor DT during non-emission periods.

Further, as the eighth transistor T8 and the ninth transistor T9 are turned on in at least one bias interval Tobs1 and Tobs2, the anode electrode (or a pixel electrode) of the first light emitting diode ED1 connected to the fourth node N4 and the anode electrode (or a pixel electrode) of the second light emitting diode ED2 connected to the fifth node N5 are initialized with the first initialization voltage VAR.

However, the gate electrodes of the seventh transistor T7, the eighth transistor T8, and the ninth transistor T9 may be configured to receive separate scan signals to be independently controlled. That is, it is not required to necessarily simultaneously apply the bias voltage to the first electrode of the driving transistor DT and the anode electrodes of the first light emitting diode ED1 and the second light emitting diode ED2 in the bias interval.

As shown in FIG. 5A, the sub pixel circuit may operate including the initialization interval Ti during the refresh period. The initialization interval Ti is an interval in which the voltage of the gate electrode of the driving transistor DT is initialized.

The first scan signal SCAN1(n), the second scan signal SCAN2(n), the third scan signal SCAN3(n), the fourth scan signal SCAN4(n), the first mode signal S(n), and the second mode signal P(n) are high voltages and the first transistor T1 and the tenth transistor T10 are turned on. The second transistor T2, the third transistor T3, the fourth transistor T4, the fifth transistor T5, the sixth transistor T6, the seventh transistor T7, the eighth transistor T8, and the ninth transistor T9 are turned off. As the first transistor T1 and the tenth transistor T10 are turned on, the gate electrode and the second electrode of the driving transistor DT connected to the second node N2 are initialized with the second initialization voltage VINI.

As shown in FIG. 5A, the sub pixel circuit may operate including the sampling interval Ts during the refresh period. The sampling interval Ts is an interval in which the threshold voltage Vth of the driving transistor DT is sampled.

The first scan signal SCAN1(n), the third signal SCAN3(n), the first mode signal S(n), and the second mode signal P(n) are high voltages and the second scan signal SCAN2(n) and the fourth scan signal SCAN4(n) are low voltages. Accordingly, the third transistor T3, the fourth transistor T4, the fifth transistor T5, the sixth transistor T6, the seventh transistor T7, the eighth transistor T8, and the ninth transistor T9 are turned off, the first transistor T1 maintains an on-state, and the second transistor T2 is turned on. That is, the second transistor T2 is turned on to apply the data voltage VDATA to the driving transistor DT and the first transistor T1 is diode-connected between the second node N2 and the third node N3 to sample the threshold voltage Vth of the driving transistor DT.

As shown in FIG. 5A, the sub pixel circuit may operate including an emission interval Te during the refresh period. The emission interval Te is an interval in which the sampled threshold voltage Vth is cancelled and the driving current corresponding to the sampled data voltage allows the first light emitting diode ED1 to emit light.

The first mode signal S(n) is a low voltage and the third transistor T3 and the fifth transistor T5 are turned on.

As the third transistor T3 operates to be turned on, the high potential driving voltage VDD is applied to the first electrode of the driving transistor DT connected to the first node N1 through the third transistor T3. The driving current ID is applied from the driving transistor DT to the first light emitting diode ED1 by the turned-on fifth transistor T5. At this time, the threshold voltage Vth of the driving transistor DT is irrelevant so that the threshold voltage Vth of the driving transistor DT is compensated to operate as a driving current Id corresponding to the sampled data voltage. Accordingly, in the first mode, the driving current Id is applied only to the first light emitting diode ED1 so that only the first light emitting diode ED1 emits light.

As shown in FIG. 5B, in the second mode, in the refresh period, a remaining interval excluding the emission interval Te operates in the same manner so that the description will be omitted. The sub pixel circuit may operate including an emission interval Te during the refresh period. The emission interval Te is an interval in which the sampled threshold voltage Vth is cancelled and the driving current corresponding to the sampled data voltage allows the second light emitting diode ED2 to emit light.

The second mode signal P(n) is a low voltage and the fourth transistor T4 and the sixth transistor T6 are turned on.

As the fourth transistor T4 operates to be turned on, the high potential driving voltage VDD is applied to the first electrode of the driving transistor DT connected to the first node N1 through the fourth transistor T4. The driving current ID is applied from the driving transistor DT to the second light emitting diode ED2 by the turned-on sixth transistor T6. Accordingly, in the third mode, the driving current Id is applied only to the third light emitting diode ED3 so that only the third light emitting diode ED3 emits light.

To drive the sub pixel circuit, the display device of the related art requires many wiring lines which apply the driving signal and the driving power. Specifically, to control the plurality of emission control transistors, an emission control signal line which applies an emission control signal is required for each of the plurality of emission control transistors so that the density of the wiring lines in the pixel is increased. Therefore, there is a problem in that it is restricted to implement a high pixels per inch (PPI) and the high resolution.

Accordingly, in the display device 100 according to the example embodiment of the present disclosure, a high pixels per inch (PPI) and the high resolution may be implemented. Specifically, the third transistor T3 and the fourth transistor T4 are connected between the high potential driving voltage line VDDL to which the high potential driving voltage VDD is applied and the source electrode of the driving transistor DT. The fifth transistor T5 is connected between the drain electrode of the driving transistor DT and the first light emitting diode ED1 and the sixth transistor T6 is connected between the drain electrode of the driving transistor DT and the second light emitting diode ED2. The third transistor T3 and the fifth transistor T5 operate by the first mode signal S(n) and the fourth transistor T4 and the sixth transistor T6 operate in accordance with the second mode signal P(n) to allow the first light emitting diode ED1 and the second light emitting diode ED2 to emit light. Accordingly, in the display device 100 according to the example embodiment of the present disclosure, the first light emitting diode ED1 or the second light emitting diode ED2 is controlled to emit light only by the first mode signal S(n) and the second mode signal P(n) in accordance with the mode selection without a separate emission control signal. Therefore, the number of wiring lines disposed in the sub pixel is reduced to lower the line density in the pixel circuit and improve the pixels per inch (PPI) and the resolution.

In the display device of the related art, in order to operate the sub pixel circuit which drives the pixel, first to fourth scan signals and first to third emission signals were required so that in order to supply the driving signals, the first to fourth scan drivers and the first to third emission drivers were necessary. Accordingly, in order to place the first to fourth scan drivers and the first to third emission drivers, there was a problem in that the area of the non-active area of the display panel was increased.

Accordingly, in the display device 100 according to the example embodiment of the present disclosure, the bezel area may be minimized or reduced. Specifically, the sub pixel circuit includes an emission transistor which operates only with the first mode signal S(n) and the second mode signal P(n) to reduce the driving signal for driving the sub pixel circuit. Accordingly, in the display device 100 according to the example embodiment of the present disclosure, the driving signal for driving the sub pixel circuit is reduced to reduce the gate driver which generates the driving signal so that the area of the non-active area in which the gate driver is disposed may be minimized or reduced, and the bezel area may be minimized or reduced.

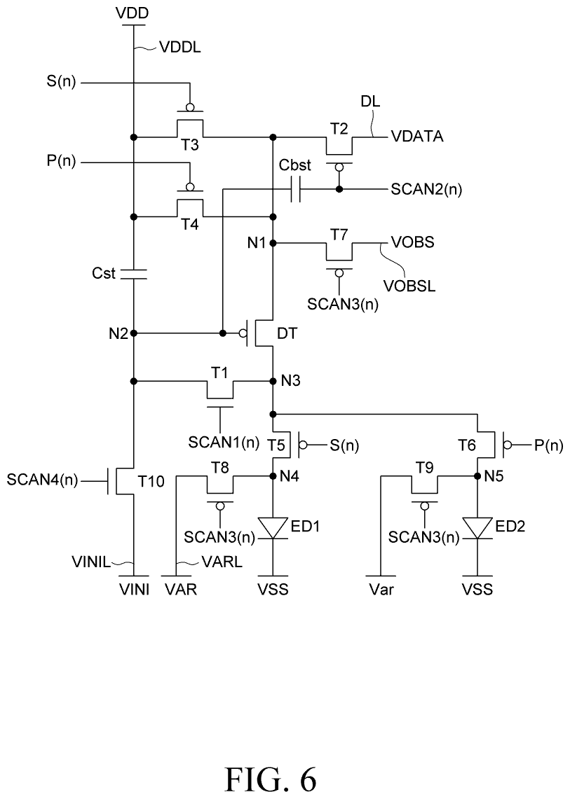

FIG. 6 is a circuit diagram of a sub pixel of a display device according to another example embodiment of the present disclosure. FIG. 6 is a circuit diagram for the same sub pixel as that of FIG. 4. FIG. 6 has the same configuration as the sub pixel circuit of FIG. 4 except for a boost capacitor Cbst, so that a redundant description will be omitted.

As shown in FIG. 6, a sub pixel circuit of a display device 200 according to another example embodiment of the present disclosure may further include a boost capacitor Cbst.

The boost capacitor Cbst may be connected between the second scan signal line to which the second scan signal SCAN2(n) is applied and the gate electrode of the driving transistor DT. For example, the first electrode of the boost capacitor Cbst may be connected to the second scan signal line to which the second scan signal SCAN2(n) is applied and the gate electrode of the second transistor T2 and the second electrode of the boost capacitor Cbst may be connected to the gate electrode of the driving transistor DT.

Accordingly, the second scan signal SCAN2(n) stored in the boost capacitor Cbst may be applied to the gate electrode of the driving transistor DT. That is, the voltage of the gate electrode of the driving transistor DT may be changed as much as a voltage variation of the second scan signal SCAN2(n).

Accordingly, in the display device 200 according to another example embodiment of the present disclosure, the first light emitting diode ED1 or the second light emitting diode ED2 may be controlled to emit light only by the first mode signal S(n) and the second mode signal P(n) in accordance with the mode selection without a separate emission control signal. Therefore, the number of wiring lines disposed in the sub pixel circuit is reduced to lower the line density in the pixel circuit and improve the pixels per inch (PPI) and the resolution.

Accordingly, in the display device 200 according to another example embodiment of the present disclosure, the driving signal for driving the sub pixel circuit is reduced to reduce the gate driver which generates the driving signal so that the area of the non-active area in which the gate driver is disposed may be minimized or reduced, and the bezel area may be minimized or reduced.

In the display device 200 according to another example embodiment of the present disclosure, the boost capacitor Cbst is connected between the second scan signal line to which the second scan signal SCAN2(n) is applied and the gate electrode of the driving transistor DT. Therefore, a voltage applied to the gate electrode of the driving transistor DT may be changed by a voltage level of the second scan signal SCAN2(n). Accordingly, in the display device 200 according to another example embodiment of the present disclosure, the voltage applied to the gate electrode of the driving transistor DT may be changed as fast as the voltage level of the second scan signal SCAN2(n). Therefore, when the color is changed to black, the color may be changed more quickly and accurately.

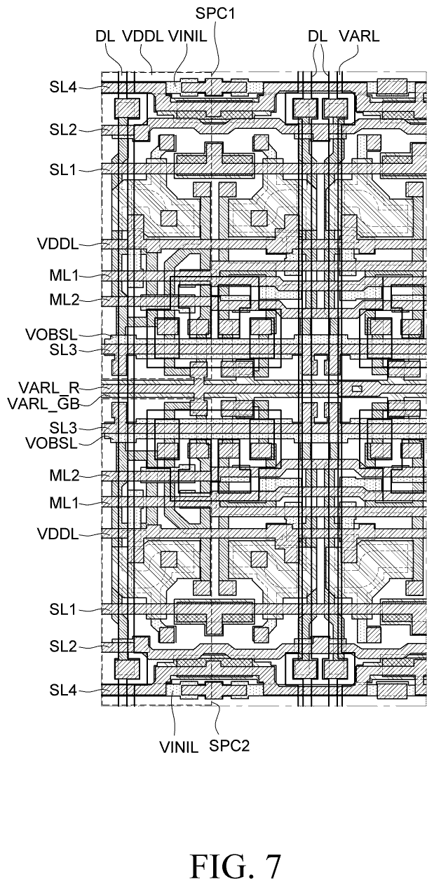

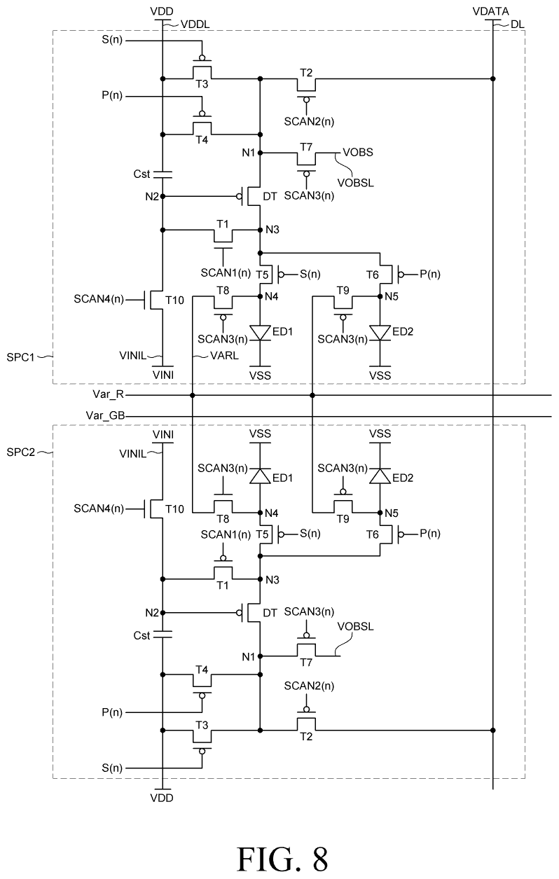

FIG. 7 is a plan view of a sub pixel of a display device according to still another example embodiment of the present disclosure. FIG. 8 is a circuit diagram for a sub pixel of FIG. 7. FIG. 7 is a view for explaining two pixels which are disposed to be adjacent in the column direction. FIG. 8 is a view for explaining two sub pixel circuits which are disposed to be adjacent in the column direction.

For the convenience of description, a horizontal direction on the plane is referred to as a first direction (or a row direction) and a vertical direction (or a perpendicular direction) on the plane is referred to as a second direction (or a column direction).

As shown in FIG. 7, in a pixel area of a display device 300 according to still another example embodiment of the present disclosure, a plurality of data lines DL, at least one first power voltage line VDDL, and at least one third power voltage line VARL may be disposed in the first direction.

For example, three data lines DL which are connected to a red sub pixel SPC1, a green sub pixel, and a blue sub pixel, respectively, may be disposed in the first direction and one high potential driving voltage line VDDL and one third power voltage line VARL may be disposed in the first direction.

In the pixel area, the first scan line SL1, the second scan line SL2, the third scan line SL3, the fourth scan line SL4, the second power voltage line VOBSL, the third power voltage lines VARL_R, VARL_GB, the fourth power voltage line VINIL, the first mode line ML1, and the second mode line ML2 may be disposed in the second direction. For example, the third scan line SL3 may be disposed on a layer different from that of the second power voltage line VOBSL so as to overlap. The fourth scan line SL4 and the fourth power voltage line VINIL may be disposed on different layer to overlap each other. For example, the first mode line ML1 and the second mode line ML2 may be disposed to be adjacent to each other. For example, a third power voltage line VARL_R which supplies the third power voltage to the red sub pixel and a third power voltage line VARL_GB which supplies the third power voltage to the blue sub pixel and the green sub pixel may be disposed on different layers to overlap each other, but it is not limited thereto.

As shown in FIGS. 7 and 8, sub pixels which are disposed to be adjacent to each other in the first direction may be symmetrically disposed. For example, with respect to the third power voltage lines VARL_R and VARL_GB, the first sub pixel SPC1 may be disposed above the third power voltage lines VARL_R and VARL_GB and the second sub pixel SPC2 may be disposed below the third power voltage lines VARL_R and VARL_GB. At this time, the driving transistor DT, the first to tenth transistors T1 to T10, and the storage capacitor Cst which configure the first sub pixel SPC1 may be disposed symmetric to the driving transistor DT, the first to tenth transistors T1 to T10, and the storage capacitor Cst which configure the second sub pixel SPC2 with respect to the third power voltage lines VARL_R and the VARL_GB.

The first sub pixel SPC1 and the second sub pixel SPC2 may share the third power voltage lines VARL_R and the VARL_GB. For example, the first sub pixel SPC1 and the second sub pixel SPC2 may be red sub pixels and may be connected to the third power voltage line VARL_R to which the third power voltage for the red sub pixel is supplied. For example, the eighth transistor T8 and the ninth transistor T9 of each of the first sub pixel SPC1 and the second sub pixel SPC2 may be connected to the third power voltage line VARL_R.

Accordingly, in the display device 300 according to still another example embodiment of the present disclosure, the first light emitting diode ED1 or the second light emitting diode ED2 may be controlled to emit light only by the first mode signal S(n) and the second mode signal P(n) in accordance with the mode selection without a separate emission control signal. Therefore, the number of wiring lines disposed in the sub pixel is reduced to lower the line density in the pixel circuit and improve the pixels per inch (PPI) and the resolution.

In the display device 300 according to still another example embodiment of the present disclosure, the driving signal for driving the sub pixel circuit is reduced to reduce the gate driver which generates the driving signal so that the area of the non-active area in which the gate driver is disposed may be minimized or reduced, and the bezel area may be minimized or reduced.

In the display device of the related art, the third power voltage lines VARL_R and VARL_GB were disposed in every sub pixel and the third power voltage lines VARL_R and VARL_GB were connected for every sub pixel so that there was a problem in that the number of wiring lines disposed in the sub pixel of the active area AA was increased.

In the display device 300 according to still another example embodiment of the present disclosure, the first sub pixel SPC1 and the second sub pixel SPC2 disposed to be adjacent to each other in the first direction are disposed to be symmetric to each other with respect to the third power voltage line VARL_R and VARL_GB. The first sub pixel SPC1 and the second sub pixel SPC2 share the third power voltage lines VARL_R and VARL_GB. The first sub pixel SPC1 and the second sub pixel SPC2 are connected to the third power voltage lines VARL_R and the VARL_GB. Accordingly, in the display device 300 according to still another example embodiment of the present disclosure, the first sub pixel SPC1 and the second sub pixel SPC2 disposed to be adjacent to each other in the first direction are connected to share the third power voltage lines VARL_R and VARL_GB. Accordingly, the number of wiring lines disposed in the sub pixel is reduced to lower the line density in the pixel circuit to increase a degree of freedom of design and improve the pixels per inch (PPI) and the resolution.

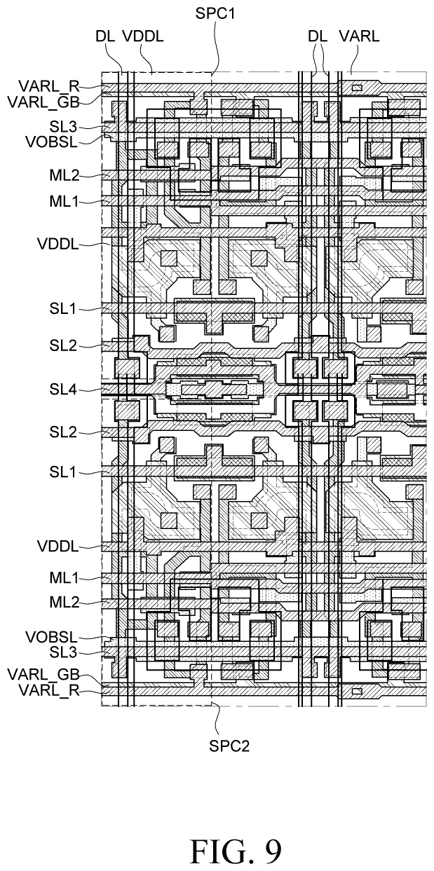

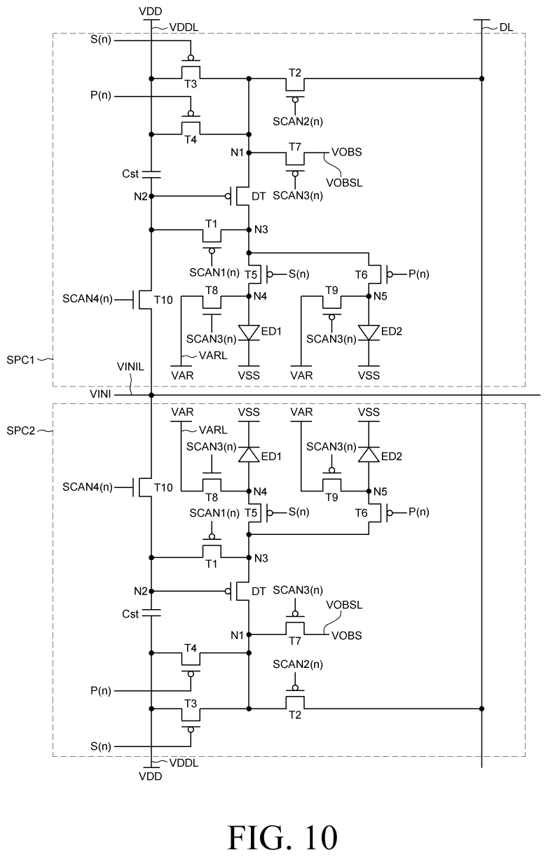

FIG. 9 is a plan view of a sub pixel of a display device according to still another example embodiment of the present disclosure. FIG. 10 is a circuit diagram for a sub pixel of FIG. 9. FIG. 9 is a view for explaining two pixels which are disposed to be adjacent in the column direction. FIG. 10 is a view for explaining two sub pixel circuits which are disposed to be adjacent in the column direction.

As shown in FIG. 9, in a pixel area of a display device 400 according to still another example embodiment of the present disclosure, a plurality of data lines DL, at least one first power voltage line VDDL, and at least one third power voltage line VARL may be disposed in the first direction.

For example, three data lines DL which are connected to a red sub pixel SPC1, a green sub pixel, and a blue sub pixel, respectively, may be disposed in the first direction and one high potential driving voltage line VDDL and one third power voltage line VARL may be disposed in the first direction.

In the pixel area, the first scan line SL1, the second scan line SL2, the third scan line SL3, the fourth scan line SL4, the second power voltage line VOBSL, the third power voltage lines VARL_R and VARL_GB, the fourth power voltage line VINIL, the first mode line ML1, and the second mode line ML2 may be disposed in the second direction. For example, the third scan line SL3 and the second power voltage line VOBSL may be disposed on different layers so as to overlap. For example, the first mode line ML1 and the second mode line ML2 may be disposed to be adjacent to each other. For example, a third power voltage line VARL_R which supplies the third power voltage to the red sub pixel and a third power voltage line VARL_GB which supplies the third power voltage to the blue sub pixel and the green sub pixel may be disposed on different layers to overlap each other. For example, the fourth scan line SL4 and the fourth power voltage line VINIL may be disposed on different layer to overlap each other, but it is not limited thereto.

As shown in FIGS. 9 and 10, sub pixels which are disposed to be adjacent to each other in the first direction may be symmetrically disposed. For example, with respect to the fourth power voltage line VINIL, the first sub pixel SPC1 may be disposed above the fourth power voltage line VINIL and the second sub pixel SPC2 may be disposed below the fourth power voltage line VINIL. At this time, the driving transistor DT, the first to tenth transistors T1 to T10, and the storage capacitor Cst which configure the first sub pixel SPC1 may be disposed symmetric to the driving transistor DT, the first to tenth transistors T1 to T10, and the storage capacitor Cst which configure the second sub pixel SPC2 with respect to the fourth power voltage line VINIL.

The first sub pixel SPC1 and the second sub pixel SPC2 may share the fourth power voltage line VINIL. For example, the first sub pixel SPC1 and the second sub pixel SPC2 may be red sub pixels and may be connected to the fourth power voltage line VINIL to which the fourth power voltage VINI is supplied. For example, the tenth transistor T10 of each of the first sub pixel SPC1 and the second sub pixel SPC2 may be connected to the fourth power voltage line VINIL.

Accordingly, in the display device 400 according to still another example embodiment of the present disclosure, the first light emitting diode ED1 or the second light emitting diode ED2 may be controlled to emit light only by the first mode signal S(n) and the second mode signal P(n) in accordance with the mode selection without a separate emission control signal. Therefore, the number of wiring lines disposed in the pixel circuit is reduced to lower the line density in the pixel circuit and improve the pixels per inch (PPI) and the resolution.

In the display device 400 according to still another example embodiment of the present disclosure, the driving signal for driving the sub pixel circuit is reduced to reduce the gate driver which generates the driving signal so that the area of the non-active area in which the gate driver is disposed may be minimized or reduced, and the bezel area may be minimized or reduced.

In the display device of the related art, the fourth power voltage line VINIL was disposed in every sub pixel and the fourth power voltage line VINIL was connected for every sub pixel so that there was a problem in that the number of wiring lines disposed in the sub pixel of the active area AA was increased.

In the display device 400 according to still another example embodiment of the present disclosure, the first sub pixel SPC1 and the second sub pixel SPC2 disposed to be adjacent to each other in the first direction are disposed to be symmetric to each other with respect to the fourth power voltage line VINIL. The first sub pixel SPC1 and the second sub pixel SPC2 share the fourth power voltage line VINIL. The first sub pixel SPC1 and the second sub pixel SPC2 are connected to the fourth power voltage line VINIL. Accordingly, in the display device 400 according to still another example embodiment of the present disclosure, the first sub pixel SPC1 and the second sub pixel SPC2 disposed to be adjacent to each other in the first direction are connected to share one fourth power voltage line VINIL. Accordingly, the number of wiring lines disposed in the sub pixel is reduced to lower the line density in the pixel circuit to increase a degree of freedom of design and improve the pixels per inch (PPI) and the resolution.

The example embodiments of the present disclosure can also be described as follows:

According to an aspect of the present disclosure, a display device includes a first light emitting diode and a second light emitting diode; a driving transistor connected between a first node and a third node to control a driving current flowing through the first light emitting diode and the second light emitting diode; a first mode selection unit connected between the first node and a first power line configured to supply a first power voltage, the first mode selection unit being configured to operate according to a mode signal; and a second mode selection unit connected between the third node and the first light emitting diode and the second light emitting diode, the second mode selection unit being configured to operate according to the mode signal.

The first mode selection unit may include a third transistor which is connected between a first power line which supplies the first power voltage and the first node to operate according to a first mode signal and a fourth transistor which is connected between the first power line and the first node to operate according to a second mode signal.

The second mode selection unit may include a fifth transistor which is connected between the driving transistor and the first light emitting diode to operate according to the first mode signal and a sixth transistor which is connected between the driving transistor and the second light emitting diode to operate according to the second mode signal.

The pixel circuit may further include a first transistor which is connected between the third node and a second node corresponding to a gate electrode of the driving transistor, a second transistor which is connected between a data line to which a data signal is applied and the first node, a seventh transistor connected between a second power line which supplies a second power voltage and the first node, an eighth transistor which is connected between a third power line which supplies a third power voltage and a fourth node corresponding to a first electrode of the first light emitting diode, a ninth transistor which is connected between the third power line and a fifth node corresponding to a first electrode of the second light emitting diode, a tenth transistor connected between a fourth power line which supplies a fourth power voltage and the second node and a storage capacitor connected between the first power line and the second node.

The driving transistor may include a first electrode connected to the first node, a second electrode connected to the third node, and a gate electrode connected to the second node, the first transistor includes a first electrode connected to the second node, a second electrode connected to the third node, and a gate electrode which receives a first scan signal, the second transistor includes a first electrode connected to the data line, a second electrode connected to the first node, and a gate electrode which receives a second scan signal, the third transistor includes a first electrode connected to the first power line, a second electrode connected to the first node, and a gate electrode which receives the first mode signal, the fourth transistor includes a first electrode connected to the first power line, a second electrode connected to the first node, and a gate electrode which receives the second mode signal, the fifth transistor includes a first electrode connected to the third node, a second electrode connected to the fourth node, and a gate electrode which receives the first mode signal, the sixth transistor includes a first electrode connected to the third node, a second electrode connected to the fifth node, and a gate electrode which receives the second mode signal, the seventh transistor includes a first electrode connected to the second power line, a second electrode connected to the first node, and a gate electrode which receives a third scan signal, the eighth transistor includes a first electrode connected to the third power line, a second electrode connected to the fourth node, and a gate electrode which receives the third scan signal, the ninth transistor includes a first electrode connected to the third power line, a second electrode connected to the fifth node, and a gate electrode which receives the third scan signal, and the tenth transistor includes a first electrode connected to the fourth power line, a second electrode connected to the second node, and a gate electrode which receives a fourth scan signal.

The first transistor and the tenth transistor are N-type oxide transistors and the driving transistor, the second transistor, the third transistor, the fourth transistor, the fifth transistor, the sixth transistor, the seventh transistor, the eighth transistor, and the ninth transistor may be P-type low temperature polycrystalline silicon (LTPS) transistors.

When the third transistor and the fifth transistors are turned on in response to the first mode signal, the first light emitting diode may emits light and when the fourth transistor and the sixth transistor are turned on in response to the second mode signal, the second light emitting diode may emits light.

The pixel circuit may further include a boost capacitor which is connected between a second scan signal line to which a second scan signal is applied and the gate electrode of the driving transistor.

According to another aspect of the present disclosure, a display device includes a substrate including an active area in which a plurality of sub pixels is disposed and a non-active area which encloses the active area; and a gate driver disposed in the non-active area. Each of the plurality of sub pixels includes a first light emitting diode and a second light emitting diode; a driving transistor connected between a first node and a third node; a first transistor connected between the third node and a second node corresponding to a gate electrode of the driving transistor; a second transistor connected between a data line configured to receive a data signal and the first node; a third transistor connected between a first power line configured to supply a first power voltage and the first node to operate according to a first mode signal; a fourth transistor connected between the first power line and the first node to operate according to a second mode signal; a fifth transistor connected between the driving transistor and the first light emitting diode to operate according to the first mode signal; a sixth transistor connected between the driving transistor and the second light emitting diode to operate according to the second mode signal; a seventh transistor connected between a second power line configured to supply a second power voltage and the first node; an eighth transistor connected between a third power line configured to supply a third power voltage and a fourth node corresponding to a first electrode of the first light emitting diode; a ninth transistor connected between the third power line and a fifth node corresponding to a first electrode of the second light emitting diode; a tenth transistor connected between a fourth power line configured to supply a fourth power voltage and the second node; and a storage capacitor connected between the first power line and the second node.

The gate driver may include a first scan driver which supplies a first scan signal to the plurality of sub pixels, a second scan driver which supplies a second scan signal to the plurality of sub pixels, a third scan driver which supplies a third scan signal to the plurality of sub pixels, a fourth scan driver which supplies a fourth scan signal to the plurality of sub pixels, a first mode signal driver which supplies the first mode signal and a second mode signal driver which supplies the second mode signal.

Each of the plurality of sub pixels may include a first lens which is disposed so as to overlap an emission area of the first light emitting diode and provides a viewing angle with a first value and a second lens which is disposed so as to overlap an emission area of the second light emitting diode and provides a viewing angle with a second value which is smaller than the viewing angle with the first value.

Each of the plurality of sub pixels may be selectively driven in a first mode and a second mode, in the first mode, the first light emitting diode may emit light so that light from the first light emitting diode is output by the first lens at the viewing angle with the first value, and in the second mode, the second light emitting diode may emit light so that light from the second light emitting diode is output by the second lens at the viewing angle with the second value.

The first transistor and the tenth transistor are N-type oxide transistors and the driving transistor, the second transistor, the third transistor, the fourth transistor, the fifth transistor, the sixth transistor, the seventh transistor, the eighth transistor, and the ninth transistor may be P-type low temperature polycrystalline silicon (LTPS) transistors.

Each of the plurality of sub pixels may further include a boost capacitor which is connected between a second scan signal line to which a second scan signal is applied and the gate electrode of the driving transistor.

In each of the plurality of sub pixels, the driving transistor may include a first electrode connected to the first node, a second electrode connected to the third node, and a gate electrode connected to the second node, the first transistor may include a first electrode connected to the second node, a second electrode connected to the third node, and a gate electrode which receives a first scan signal, the second transistor may include a first electrode connected to the data line, a second electrode connected to the first node, and a gate electrode which receives a second scan signal, the third transistor may include a first electrode connected to the first power line, a second electrode connected to the first node, and a gate electrode which receives the first mode signal, the fourth transistor may include a first electrode connected to the first power line, a second electrode connected to the first node, and a gate electrode which receives the second mode signal, the fifth transistor may include a first electrode connected to the third node, a second electrode connected to the fourth node, and a gate electrode which receives the first mode signal, the sixth transistor may include a first electrode connected to the third node, a second electrode connected to the fifth node, and a gate electrode which receives the second mode signal, the seventh transistor may include a first electrode connected to the second power line, a second electrode connected to the first node, and a gate electrode which receives a third scan signal, the eighth transistor may include a first electrode connected to the third power line, a second electrode connected to the fourth node, and a gate electrode which receives the third scan signal, the ninth transistor may include a first electrode connected to the third power line, a second electrode connected to the fifth node, and a gate electrode which receives the third scan signal, and the tenth transistor may include a first electrode connected to the fourth power line, a second electrode connected to the second node, and a gate electrode which receives a fourth scan signal.

A plurality of sub pixels may be disposed to be adjacent in a column direction, among the plurality of sub pixels, shares the third power line.

A plurality of sub pixels may be disposed to be adjacent in a column direction, among the plurality of sub pixels, shares the fourth power line.

Although example embodiments of the present disclosure have been described in detail with reference to the accompanying drawings, the present disclosure is not limited thereto and may be embodied in many different forms without departing from the technical concept of the present disclosure. Therefore, the above example embodiments of the present disclosure are provided for illustrative purposes only and are not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A pixel circuit, comprising:
a first light emitting diode and a second light emitting diode;
a driving transistor connected between a first node and a third node to control a driving current flowing through the first light emitting diode and the second light emitting diode;
a first mode selection unit connected between the first node and a first power line configured to supply a first power voltage, the first mode selection unit being configured to operate according to a mode signal; and
a second mode selection unit connected between the third node and the first light emitting diode and the second light emitting diode, the second mode selection unit being configured to operate according to the mode signal.

2. The pixel circuit according to claim 1, wherein the first mode selection unit includes:
a third transistor connected between the first power line and the first node to operate according to a first mode signal; and
a fourth transistor connected between the first power line and the first node to operate according to a second mode signal.

3. The pixel circuit according to claim 2, wherein the second mode selection unit includes:
a fifth transistor connected between the driving transistor and the first light emitting diode to operate according to the first mode signal; and
a sixth transistor connected between the driving transistor and the second light emitting diode to operate according to the second mode signal.

4. The pixel circuit according to claim 3, further comprising:
a first transistor connected between the third node and a second node corresponding to a gate electrode of the driving transistor;
a second transistor connected between a data line configured to receive a data signal and the first node;
a seventh transistor connected between a second power line configured to supply a second power voltage and the first node;
an eighth transistor connected between a third power line configured to supply a third power voltage and a fourth node corresponding to a first electrode of the first light emitting diode;
a ninth transistor connected between the third power line and a fifth node corresponding to a first electrode of the second light emitting diode;
a tenth transistor connected between a fourth power line configured to supply a fourth power voltage and the second node; and
a storage capacitor connected between the first power line and the second node.

5. The pixel circuit according to claim 4, wherein:
the driving transistor includes a first electrode connected to the first node, a second electrode connected to the third node, and a gate electrode connected to the second node;
the first transistor includes a first electrode connected to the second node, a second electrode connected to the third node, and a gate electrode configured to receive a first scan signal;
the second transistor includes a first electrode connected to the data line, a second electrode connected to the first node, and a gate electrode configured to receive a second scan signal;
the third transistor includes a first electrode connected to the first power line, a second electrode connected to the first node, and a gate electrode configured to receive the first mode signal;
the fourth transistor includes a first electrode connected to the first power line, a second electrode connected to the first node, and a gate electrode configured to receive the second mode signal;
the fifth transistor includes a first electrode connected to the third node, a second electrode connected to the fourth node, and a gate electrode configured to receive the first mode signal;
the sixth transistor includes a first electrode connected to the third node, a second electrode connected to the fifth node, and a gate electrode configured to receive the second mode signal;
the seventh transistor includes a first electrode connected to the second power line, a second electrode connected to the first node, and a gate electrode configured to receive a third scan signal;
the eighth transistor includes a first electrode connected to the third power line, a second electrode connected to the fourth node, and a gate electrode configured to receive the third scan signal;
the ninth transistor includes a first electrode connected to the third power line, a second electrode connected to the fifth node, and a gate electrode configured to receive the third scan signal; and
the tenth transistor includes a first electrode connected to the fourth power line, a second electrode connected to the second node, and a gate electrode configured to receive a fourth scan signal.

6. The pixel circuit according to claim 4, wherein:
the first transistor and the tenth transistor are N-type oxide transistors; and
the driving transistor, the second transistor, the third transistor, the fourth transistor, the fifth transistor, the sixth transistor, the seventh transistor, the eighth transistor, and the ninth transistor are P-type low temperature polycrystalline silicon (LTPS) transistors.

7. The pixel circuit according to claim 4, wherein:
when the third transistor and the fifth transistor are turned on in response to the first mode signal, the first light emitting diode is configured to emit light; and
when the fourth transistor and the sixth transistor are turned on in response to the second mode signal, the second light emitting diode is configured to emit light.

8. The pixel circuit according to claim 4, further comprising:
a boost capacitor connected between a second scan signal line configured to receive a second scan signal and the gate electrode of the driving transistor.

9. A display device, comprising:
a substrate including:
an active area in which a plurality of sub pixels is disposed; and
a non-active area which encloses the active area; and
a gate driver disposed in the non-active area,
wherein each of the plurality of sub pixels includes:
a first light emitting diode and a second light emitting diode;
a driving transistor connected between a first node and a third node;
a first transistor connected between the third node and a second node corresponding to a gate electrode of the driving transistor;
a second transistor connected between a data line configured to receive a data signal and the first node;
a third transistor connected between a first power line configured to supply a first power voltage and the first node to operate according to a first mode signal;
a fourth transistor connected between the first power line and the first node to operate according to a second mode signal;
a fifth transistor connected between the driving transistor and the first light emitting diode to operate according to the first mode signal;
a sixth transistor connected between the driving transistor and the second light emitting diode to operate according to the second mode signal;
a seventh transistor connected between a second power line configured to supply a second power voltage and the first node;
an eighth transistor connected between a third power line configured to supply a third power voltage and a fourth node corresponding to a first electrode of the first light emitting diode;
a ninth transistor connected between the third power line and a fifth node corresponding to a first electrode of the second light emitting diode;
a tenth transistor connected between a fourth power line configured to supply a fourth power voltage and the second node; and
a storage capacitor connected between the first power line and the second node.

10. The display device according to claim 9, wherein the gate driver includes:
a first scan driver configured to supply a first scan signal to the plurality of sub pixels;
a second scan driver configured to supply a second scan signal to the plurality of sub pixels;
a third scan driver configured to supply a third scan signal to the plurality of sub pixels;
a fourth scan driver configured to supply a fourth scan signal to the plurality of sub pixels;
a first mode signal driver configured to supply the first mode signal; and
a second mode signal driver configured to supply the second mode signal.

11. The display device according to claim 9, wherein each of the plurality of sub pixels includes:
a first lens which is disposed so as to overlap an emission area of the first light emitting diode and provides a viewing angle with a first value; and
a second lens which is disposed so as to overlap an emission area of the second light emitting diode and provides a viewing angle with a second value smaller than the viewing angle with the first value.

12. The display device according to claim 11, wherein:
each of the plurality of sub pixels is selectively driven in a first mode and a second mode;
in the first mode, the first light emitting diode is configured to emit light so that light from the first light emitting diode is output by the first lens at the viewing angle with the first value; and
in the second mode, the second light emitting diode is configured to emit light so that light from the second light emitting diode is output by the second lens at the viewing angle with the second value.

13. The display device according to claim 9, wherein:
the first transistor and the tenth transistor are N-type oxide transistors; and
the driving transistor, the second transistor, the third transistor, the fourth transistor, the fifth transistor, the sixth transistor, the seventh transistor, the eighth transistor, and the ninth transistor are P-type low temperature polycrystalline silicon (LTPS) transistors.

14. The display device according to claim 9, wherein each of the plurality of sub pixels further includes a boost capacitor connected between a second scan signal line configured to receive a second scan signal and the gate electrode of the driving transistor.

15. The display device according to claim 9, wherein in each of the plurality of sub pixels:
the driving transistor includes a first electrode connected to the first node, a second electrode connected to the third node, and a gate electrode connected to the second node;
the first transistor includes a first electrode connected to the second node, a second electrode connected to the third node, and a gate electrode configured to receive a first scan signal;
the second transistor includes a first electrode connected to the data line, a second electrode connected to the first node, and a gate electrode configured to receive a second scan signal;
the third transistor includes a first electrode connected to the first power line, a second electrode connected to the first node, and a gate electrode configured to receive the first mode signal;
the fourth transistor includes a first electrode connected to the first power line, a second electrode connected to the first node, and a gate electrode configured to receive the second mode signal;
the fifth transistor includes a first electrode connected to the third node, a second electrode connected to the fourth node, and a gate electrode configured to receive the first mode signal;
the sixth transistor includes a first electrode connected to the third node, a second electrode connected to the fifth node, and a gate electrode configured to receive the second mode signal;
the seventh transistor includes a first electrode connected to the second power line, a second electrode connected to the first node, and a gate electrode configured to receive a third scan signal;
the eighth transistor includes a first electrode connected to the third power line, a second electrode connected to the fourth node, and a gate electrode configured to receive the third scan signal;
the ninth transistor includes a first electrode connected to the third power line, a second electrode connected to the fifth node, and a gate electrode configured to receive the third scan signal; and
the tenth transistor includes a first electrode connected to the fourth power line, a second electrode connected to the second node, and a gate electrode configured to receive a fourth scan signal.

16. The display device according to claim 9, wherein a plurality of sub pixels disposed to be adjacent in a column direction, among the plurality of sub pixels, share the third power line.

17. The display device according to claim 9, wherein a plurality of sub pixels disposed to be adjacent in a column direction, among the plurality of sub pixels, share the fourth power line.
